(19) United States
(12) Patent Application Publication
(10) Pub. No.: US 2023/0318599 A1
(43) Pub. Date: Oct. 5, 2023

(54) RADIO FREQUENCY SWITCH CIRCUIT AND SWITCH INTEGRATED CIRCUIT

(71) Applicant: SAMSUNG ELECTRO-MECHANICS CO., LTD., Suwon-si (KR)

(72) Inventors: Shinhaeng HEO, Suwon-si (KR); Jongmo LIM, Suwon-si (KR); Wonsun HWANG, Suwon-si (KR); Dongil KANG, Suwon-si (KR); Byeonghak JO, Suwon-si (KR)

(73) Assignee: SAMSUNG ELECTRO-MECHANICS CO., LTD., Suwon-si (KR)

(21) Appl. No.: 17/865,865

(22) Filed: Jul. 15, 2022

(30) Foreign Application Priority Data
Feb. 14, 2022 (KR) 10-2022-0018911

(51) Int. Cl. H03K 17/693; H03K 17/687; H03K 17/06

(52) U.S. Cl. CPC H03K 17/693; H03K 17/063; H03K 17/6871

(57) ABSTRACT

A radio frequency (RF) switch circuit is provided. The RF switch circuit may include: a first switch integrated circuit (IC) that includes a first switch core having a first switch structure, a first input pin to which a first switching control signal is inputted, and a second input pin to which a first mode voltage corresponding to the first switch structure is applied; and a second switch that includes a second switch core having a second switch structure, a third input pin to which a second switching control signal is inputted, and a fourth input pin to which a second mode voltage corresponding to the second switch structure is applied.

### CROSS-REFERENCE TO RELATED APPLICATION

This application claims the benefit the benefit under 35 USC §119(a) of Korean Patent Application No. 10-2022-0018911, filed on Feb. 14, 2022, in the Korean Intellectual Property Office, the entire disclosure of which is incorporated herein by reference for all purposes.

### BACKGROUND

### 1. Field

This following description relates to a radio frequency (RF) switch circuit and a switch integrated circuit (IC).

### 2. Description of Related Art

An RF switch circuit is a device that may be mainly used at transmitting and receiving terminals of a communication device, and may transmit or block an RF signal. The form factor of recent RF switch circuits has become more miniaturized, and the performance of recent RF switches has improved.

As mobile communication technology evolves, multiple signal paths are desired. In order to implement multiple signal paths and various functions, a structure of a switch core included in the RF switch circuit should also be diversified. For example, the switch core may have various structures such as single pole double throw (SPDT), single pole three throw (SP3T), double pole double throw (DPDT), multi pole multi throw (MPMT), and the like. When a switch core having one of the various structures is manufactured, it may be desirable to restrict the operation of other functions. Accordingly, it may be desirable to implement a switch core that implements the various structures.

The above information disclosed in this Background section is only for enhancement of understanding of the background, and therefore it may contain information that does not form the prior art that is already known in this country to a person of ordinary skill in the art.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a radio frequency (RF) switch circuit including a first switch integrated circuit (IC) comprising a first switch core which has a first switch structure, a first input pin to which a first switching control signal is inputted, and a second input pin to which a first mode voltage corresponding to the first switch structure is input; and a second switch IC comprising a second switch core which has a second switch structure, a third input pin to which a second switching control signal is inputted, and a fourth input pin to which a second mode voltage corresponding to the second switch structure is inputted.

The second switch structure may be different from the first switch structure, and the second mode voltage may have a different voltage level from a voltage level of the first mode voltage.

The first switch core may include a plurality of first switches, the second switch core may include a plurality of second switches, and a connecting structure between terminals in the plurality of first switches may be different from a connecting structure between terminals in the plurality of second switches.

Each of the plurality of first switches may be configured to have a single pole single throw (SPST) structure, and each of the plurality of second switches may be configured to have an SPST structure.

A structure with respect to a pole and a throw with which the first switch structure is formed may be different from a structure with respect to a pole and a throw with which the second switch structure is formed.

The first switch IC may further include a first decoder configured to perform a decoding operation by implementing the first switching control signal and the first mode voltage, and generate a switching driving signal, and the second switch IC may further include a second decoder configured to perform a decoding operation by implementing the second switching control signal and the second mode voltage, and generate a switching driving signal.

The first switch IC may further include a first analog-digital converter configured to convert the first mode voltage to a digital signal, and output the converted first mode voltage to the first decoder, and the second switch IC may further include a second analog-digital converter configured to convert the second mode voltage into a digital signal and output the converted second mode voltage to the second decoder.

The first switching control signal and the second switching control signal may be configured to have a same number of bits.

The first switching control signal and the second switching control signal may each be a general-purpose input output (GPIO).

Each of the plurality of first switches may include a plurality of transistors configured to form one of a T structure and a pi (π) structure, and each of the plurality of second switches comprises a plurality of transistors configured to form one of a T structure and a pi (π) structure.

Each of the first input pin and the third input pin may include a plurality of input pins, and a number of the first input pins may be equal to a number of the third input pins.

In a general aspect, a switch integrated circuit (IC) includes a switch core comprising a plurality of switches, and in which a pole and a throw are formed by a connecting structure between terminals in the plurality of switches; a first input pin to which a switching control signal that controls the plurality of switches is inputted; and a second input pin to which a mode voltage corresponding to the connecting structure is applied.

Each of the plurality of switches may be configured to have a single pole single throw (SPST) structure.

The switch IC may further include a decoder configured to perform a decoding operation based on the switching control signal and the mode voltage.

The switch IC may further include an analog-digital converter configured to convert the mode voltage into a digital signal to output the converted mode voltage to the decoder.

The switching control signal may be a general-purpose input output (GPIO).

Each of the plurality of switches may include a plurality of transistors configured to form one of a T structure and a pi (π) structure.

Other features and aspects will be apparent from the following detailed description, the drawings, and the claims.

### BRIEF DESCRIPTION OF DRAWINGS

FIG. 1 illustrates an example switch core, in accordance with one or more embodiments.

FIG. 2A illustrates an example in which the switch core of FIG. 1 has a symmetric single pole double throw (SPDT) structure.

FIG. 2B illustrates an example in which the switch core of FIG. 1 has a non-symmetric single pole double throw (SPDT) structure.

FIG. 2C illustrates an example in which the switch core of FIG. 1 has a single pole four throw (SP4T) structure.

FIG. 2D illustrates an example in which the switch core of FIG. 1 has a double pole double throw (DPDT) structure.

FIG. 3A illustrates an example inner configuration of one switch, in accordance with one or more embodiments.

FIG. 3B illustrates an example inner configuration of one switch, in accordance with one or more embodiments.

FIG. 4 illustrates a switch integrated circuit (IC), in accordance with one or more embodiments.

FIG. 5A illustrates an example mode voltage generating circuit, in accordance with one or more embodiments.

FIG. 5B illustrates an example mode voltage generating circuit, in accordance with one or more embodiments.

FIG. 5C illustrates an example mode voltage generating circuit, in accordance with one or more embodiments.

FIG. 5D illustrates an example mode voltage generating circuit, in accordance with one or more embodiments.

FIG. 5E illustrates an example mode voltage generating circuit, in accordance with one or more embodiments.

FIG. 6 illustrates an example RF switch circuit, in accordance with one or more embodiments.

FIG. 7A illustrates an example switching driving signal based on a first mode voltage and a switching control signal, in accordance with one or more embodiments.

FIG. 7B illustrates an example switching driving signal based on a second mode voltage and a switching control signal, in accordance with one or more embodiments.

FIG. 7C illustrates an example switching driving signal based on a third mode voltage and a switching control signal, in accordance with one or more embodiments.

Throughout the drawings and the detailed description, unless otherwise described or provided, the same drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

In one or more examples, the number of input pins may be reduced by setting a mode voltage to another voltage according to a switch structure included in one switch core,

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

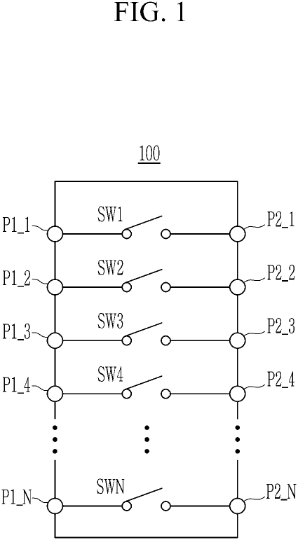

FIG. 1 illustrates an example switch core 100, in accordance with one or more embodiments.

As illustrated in FIG. 1, the example switch core 100, in accordance with one or more embodiments, may include a plurality of switches SW1 to SWN. In FIG. 1, N may be a natural number of 2 or more.

The first switch SW1 may be connected between a port P1_1 and a port P2_1, and may switch an RF path formed between the port P1_1 and the port P2_1. That is, a first end of the first switch SW1 may be connected to the port P1_1, and a second end of the first switch SW1 may be connected to the port P2_1.

The second switch SW2 may be connected between a port P1_2 and a port P2_2, and may switch an RF path formed between the port P1_2 and the port P2_2. That is, a first end of the second switch SW2 may be connected to the port P1_2, and a second end of the second switch SW2 may be connected to the port P2_2.

The third switch SW3 may be connected between a port P1_3 and a port P2_3, and may switch an RF path formed between the port P1_3 and the port P2_3. That is, a first end of the third switch SW3 may be connected to the port P1_3, and a second end of the third switch SW3 may be connected to the port P2_3.

The fourth switch SW4 may be connected between a port P1_4 and a port P2_4, and may switch an RF path formed between the port P1_4 and the port P2_4. That is, a first end of the fourth switch SW4 may be connected to the port P1_4, and a second end of the fourth switch SW4 may be connected to the port P2_4.

Additionally, the N-th switch SWN may be connected between a port P1_N and a port P2_N, and may switch an RF path formed between the port P1_N and the port P2_N. That is, a first end of the N-th switch SWN may be connected to the port P1_N, and a second end of the N-th switch SWN may be connected to the port P2_N.

In other words, the switch core 100, in accordance with one or more embodiments, may include a plurality of SPST switches. That is, each of the plurality of switches SW1 to SWN may have a Single Pole Single Throw (SPST) structure.

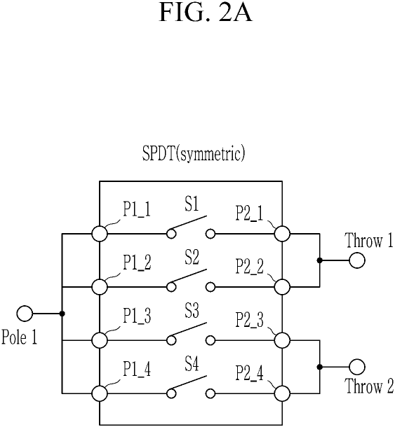

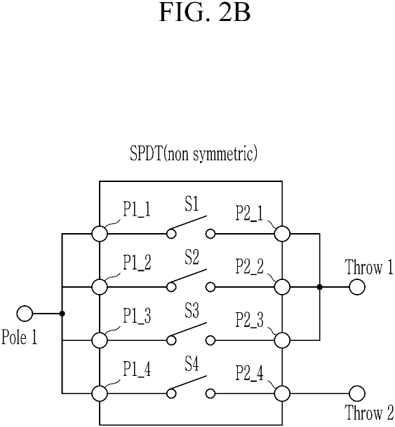

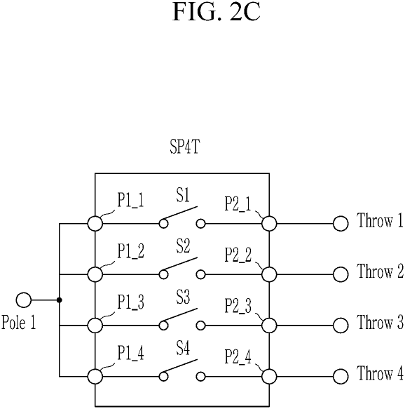

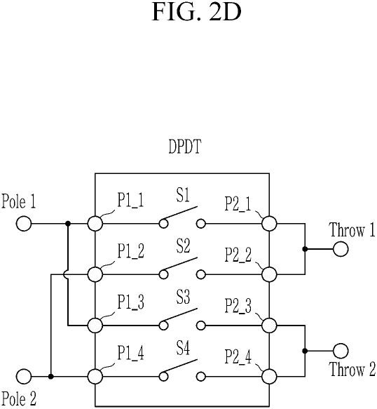

In an example, port terminals of the switch core 100, in accordance with one or more embodiments, may be connected to each other in an integrated circuit to provide various switch structures, which will be described with reference to FIG. 2A to FIG. 2D below. FIG. 2A to FIG. 2D respectively illustrate various switch structures in examples in which the switch core 100 has four switches SW1 to SW4. However, this is only an example, and switch structures may also be applied to examples in which the switch core 100 has two or more switches.

FIG. 2A illustrates an example in which the switch core 100 of FIG. 1 has a symmetric Single Pole Double Throw (SPDT) structure, in accordance with one or more embodiments.

As illustrated in FIG. 2A, in the example switch core 100 of FIG. 1, the port P1_1, the port P1_2, the port P1_3, and the port P1_4 may be connected to each other to form one pole (Pole 1). That is, a first end of the first switch S1, a first end of the second switch S2, a first end of the third switch S3, and a first end of the fourth switch S4 may be connected to each other. Additionally, in the switch core 100, the port P2_1 and the port P2_2 may be connected to each other to form one throw (Throw 1), and the port P2_3 and the port P2_4 may be connected to each other to form another throw (Throw 2). That is, a second end of the first switch SW1 and a second end of the second switch SW2 may be connected to each other, and a second end of the third switch SW3 and a second end of the fourth switch SW4 may be connected to each other. Accordingly, the switch core as illustrated in FIG. 2A may have a symmetric SPDT structure by forming one pole and two throws.

FIG. 2B illustrates an example in which the switch core 100 of FIG. 1 has a non-symmetric SPDT structure.

As illustrated in FIG. 2B, in the switch core 100 of FIG. 1, the port P1_1, the port P1_2, the port P1_3, and the port P1_4 may be connected to each other to form one pole (Pole 1). That is, a first end of the first switch S1, a first end of the second switch S2, a first end of the third switch S3, and a first end of the fourth switch S4 may be connected to each other. Additionally, in the switch core 100, the port P2_1, the port P2_2, and the port P2_3 may be connected to each other to form one throw (Throw 1), and the port P2_4 may not nbe connected to another port, so that another throw (Throw 2) may be formed. That is, the second end of the first switch SW1, the second end of the second switch SW2 and the second end of the third switch SW3 may be connected to each other. Accordingly, the switch core as illustrated in FIG. 2B may have a non-symmetric SPDT structure by forming one pole and two throws.

FIG. 2C illustrates an example in which the switch core 100 of FIG. 1 has a Single Pole 4 Throw (SP4T) structure.

As illustrated in FIG. 2C, in the switch core 100 of FIG. 1, the port P1_1, the port P1_2, the port P1_3, and the port P1_4 may be connected to each other to form one pole (Pole 1). That is, a first end of the first switch SW1, a first end of the second switch SW2, a first end of the third switch SW3, and a first end of the fourth switch SW4 may be connected to each other. Additionally, in the switch core 100, the port P2_1, the port P2_2, the port P2_3, and the port P2_4 may not be connected to other ports, so that each thereof may form one throw. That is, the second end of the first switch SW1, the second end of the second switch SW2, the second end of the third switch SW3, and the second end SW4 of the fourth switch correspond to a throw, respectively. Accordingly, the switch core as illustrated in FIG. 2C may have an SP4T structure by forming one pole and four throws.

FIG. 2D illustrates an example in which the switch core 100 of FIG. 1 has a Double Pole Double Throw (DPDT) structure.

As illustrated in FIG. 2D, in the switch core 100 of FIG. 1, the port P1_1 and the port P1_3 may be connected to each other to form one pole (Pole 1), and the port P1_2 and the port P1_4 may be connected to each other to form another pole (Pole 2). That is, a first end of the first switch S1 and a first end of the third switch S3 may be connected to each other, and a first end of the second switch S2 and a first end of the fourth switch S4 may be connected to each other. Additionally, in the switch core 100, the port P2_1 and the port P2_2 may be connected to each other to form one throw (Throw 1), and the port P2_3 and the port P2_4 may be connected to each other to form another throw (Throw 2). That is, the second end of the first switch SW1 and the second end of the second switch SW2 may be connected to each other, and the other end of the third switch SW3 and the other end of the fourth switch SW4 may be connected to each other. Accordingly, the switch core as shown in FIG. 2D may have a DPDT structure by forming two poles and two throws.

As described above, the example switch core 100 may provide various switch structures through a reconfigurable plurality of the switches SW1 to SWN.

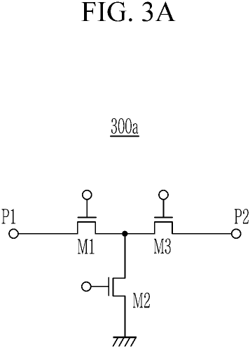

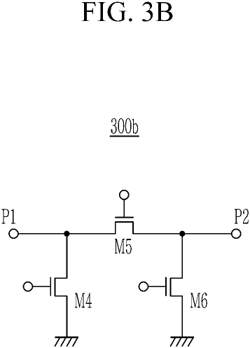

FIG. 3A illustrates an example inner configuration of one switch, in accordance with one or more embodiments.

Referring to FIG. 3A, a switch 300a may correspond to each of the plurality of switches SW1 to SWN of FIG. 1. That is, each of the plurality of switches SW1 to SWN may be configured in a manner that is similar to the switch 300a.

As illustrated in FIG. 3A, the switch 300a may include a transistor M1, a transistor M2, and a transistor M3. The transistors M1 to M3 illustrated in FIG. 3A may be implemented as various transistors such as, but not limited to, a field effect transistor (FET), a bipolar transistor, and the like, which have a switching function. Additionally, the transistors M1 to M3 may be N-type or P-type transistors. Hereinafter, for better understanding and ease of description, it is assumed that the transistors M1 to M3 are FETs, but the transistors M1 to M3 may be replaced with other transistors. FIG. 3A illustrates an example in which each of the transistors M1 to M3 is implemented as one transistor. However, this is only an example, and the transistors M1 to M3 may be implemented as a stacked plurality of transistors.

Referring to FIG. 3A, a first terminal of the transistor M1 may be connected to the port P1, and a second terminal of the transistor M1 may be connected to a first terminal of the transistor M2. A second terminal of the transistor M2 may be connected to ground. Additionally, a first terminal of the transistor M3 may be connected to the second terminal of the transistor M1, and a second terminal of the transistor M3 may be connected to the port P2. A switching driving signal may be applied to a control terminal of each of the transistors M1 to M3. In an example, the port P1 may correspond to one of the ports P1_1 to P1_N of FIG. 1, and the port P2 may correspond to one of the ports P2_1 to P2_N of FIG. 1.

In a turn-on operation of the switch 300a, the transistor M1 and the transistor M3 may be turned on, and the transistor M2 may be turned off. Additionally, in a turn-off operation of the switch 300a, the transistor M1 and the transistor M3 may be turned off, and the transistor M2 may be turned on.

In an example, since the transistors M1 to M3 may be connected to each other to have a T structure, the switch 300a may be a T-type of switch. Accordingly, when it is an off-capacitance of a shunt transistor (that is, the transistor M2) that affects insertion loss, the switch 300a may be applied.

FIG. 3B illustrates an example of an inner configuration of one switch, in accordance with one or more embodiments.

In FIG. 3B, a switch 300b may correspond to each of the plurality of switches SW1 to SWN of FIG. 1. That is, each of the plurality of switches SW1 to SWN may be configured in a manner that is similar to the switch 300b.

As illustrated in FIG. 3B, the switch 300b may include a transistor M4, a transistor M5, and a transistor M6. The transistors M4 to M6 illustrated in FIG. 3B may be implemented as various transistors such as, but not limited to, a field effect transistor (FET), a bipolar transistor, and the like, which have a switching function. Additionally, the transistors M4 to M6 may be N-type or P-type transistors. Hereinafter, for better understanding and ease of description, it is assumed that the transistors M4 to M6 are FETs. However, the transistors M4 to M6 may be replaced with other transistors. FIG. 3B illustrates an example in which each of the transistors M4 to M6 is implemented as one transistor. However, this is only an example, and the transistors M4 to M6 may be implemented as a stacked plurality of transistors.

A first terminal of the transistor M4 may be connected to the port P1, and a second terminal of the transistor M4 may be connected to the ground. A first terminal of the transistor M5 may be connected to the port P1, and a second terminal of the transistor M5 may be connected to the port P2. Additionally, a first terminal of the transistor M6 may be connected to the port P2, and a second terminal of the transistor M6 may be connected to the ground. A switching driving signal may be applied to a control terminal of each of the transistors M4 to M6. The port P1 may correspond to one of the ports P1_1 to P1_N of FIG. 1, and the port P2 may correspond to one of the ports P2_1 to P2_N of FIG. 1.

In a turn-on operation of the switch 300b, the transistor M5 may be turned on, and the transistor M4 and the transistor M6 may be turned off. Additionally, in a turn-off operation of the switch 300b, the transistor M5 may be turned off, and the transistor M4 and the transistor M6 may be turned on.

Since the transistors M4 to M6 may be connected to each other to have a pi (π) structure, the switch 300b may be a pi (π) type of switch. Accordingly, when it is an on-resistance of a series transistor (that is, the transistor M5) that affects insertion loss, the switch 300n may be applied.

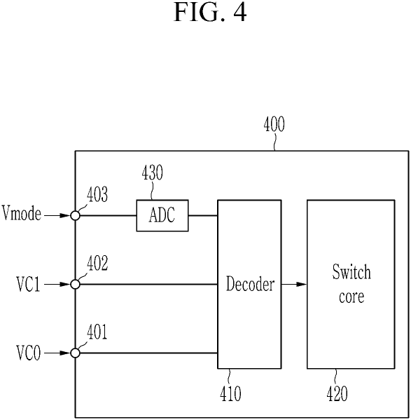

FIG. 4 illustrates an example switch IC 400, in accordance with one or more embodiments.

As illustrated in FIG. 4, the example switch IC 400 may include a decoder 410, a switch core 420, and an analog-digital converter (ADC) 430. Additionally, the switch IC 400 may include a plurality of input pins 401 to 403 to which a signal is inputted from an external source.

Switching control signals VC0 and VC1 may be respectively inputted to the input pins 401 and 402 from an external source. The switching control signals VC0 and VC1 may be control signals to control switches included in the switch core 420. In a non-limiting example, the switching control signals VC0 and VC1 may be general purpose input output (GPIO) input bits.

A mode voltage (Vmode) may be applied to the input pin 403. The mode voltage (Vmode) may have a different voltage corresponding to a switch structure of the switch core 420. The mode voltage (Vmode) may be an analog voltage. In an example, when the switch core 420 has a symmetric SPDT as illustrated in FIG. 2A, the mode voltage (Vmode) may be a first mode voltage (Vmode1). When the switch core 420 is a non-symmetric SPDT as illustrated in FIG. 2B, the mode voltage (Vmode) may be a second mode voltage (Vmode2). Additionally, when the switch core 420 is an SP4T as shown in FIG. 2C, the mode voltage (Vmode) may be a third mode voltage (Vmode3). In an example, the first mode voltage (Vmode1) to the third mode voltage (Vmode3) may have different voltage levels. Since different mode voltages (Vmode) may be applied to the input pin 403 according to the switch structure of the switch core 420, it is possible to reduce the number of pins (for example, 401 and 402) to which the switching control signal is inputted. That is, due to the input pin 403 to which the mode voltage (Vmode) is applied, the number of input bits of the switching control signal may be reduced. This will be described in more detail below.

The ADC 430 may receive the mode voltage (Vmode) from the input pin 403 to convert the mode voltage (Vmode) into a digital signal. Since the mode voltage (Vmode) is an analog signal, the ADC 430 converts an analog signal into a digital signal.

The decoder 410 may receive the switching control signals VC0 and VC1 from the input pins 401 and 402, and may receive a digital signal of the mode voltage (Vmode) from the ADC 430. The decoder 410 may perform decoding by implementing the switching control signals VC0 and VC1 and the digital signal of the mode voltage (Vmode), and generate the switching driving signal. The switching driving signal generated by the decoder 410 may be applied to the switch core 420, and the switch core 420 may perform a switching operation according to the switching driving signal.

The switch core 420 may be the switch core 100 of FIG. 1. Additionally, the switch core 420 may have one of the switch structures as illustrated in FIG. 2A to FIG. 2D. Each switch included in the switch core 420 may be switched by a switching driving signal inputted from the decoder 410.

Although not illustrated in FIG. 4, a switching driving circuit (for example, a buffer) may be positioned between the decoder 410 and the switch core 420.

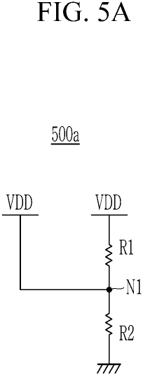

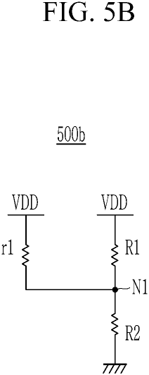

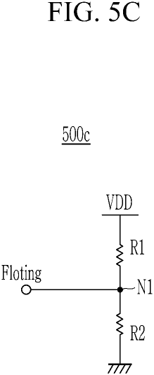

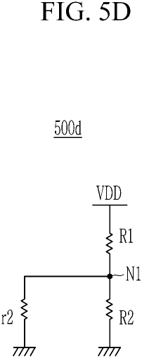

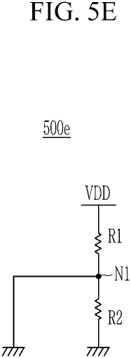

Hereinafter, a mode voltage generating circuit that generates the mode voltage (Vmode) will be described with reference to FIG. 5A to FIG. 5C. The mode voltage generating circuit described below may be implemented inside the switch IC 400 of FIG. 4, or may be implemented as an external separate device.

FIG. 5A illustrates an example mode voltage generating circuit 500a, in accordance with one or more embodiments.

As illustrated in FIG. 5A, the example mode voltage generating circuit 500a may include a power voltage VDD, a resistor R1, and a resistor R2.

A first end of the resistor R1 is connected to the power voltage, and the resistor R2 is connected between a second end of the resistor R1 and the ground. In FIG. 5A, a contact point between the resistor R1 and the resistor R2 is denoted by node N1. A voltage of the contact point N1 corresponds to the mode voltage (Vmode). The mode voltage (Vmode) may be set according to a circuit configuration connected to the contact point N1. Referring to FIG. 5A, the power voltage VDD may be connected to the contact point N1. Accordingly, since the voltage of the contact point N1 is VDD, a mode voltage (Vmode_500a) generated by the mode voltage generating circuit 500a is VDD.

FIG. 5B illustrates an example mode voltage generating circuit 500b, in accordance with one or more embodiments.

As illustrated in FIG. 5B, the example mode voltage generating circuit 500b may be similar to the example mode voltage generating circuit 500a of FIG. 5A except that a circuit configuration connected to the contact point N1 is different.

Referring to FIG. 5B, a power voltage VDD having a resistor r1 may be connected to the contact point N1. That is, the resistor r1 may be connected between the power voltage VDD and the contact point N1. Accordingly, a voltage of the contact point N1 may be represented by Equation 1 below. That is, a mode voltage (Vmode_500b) generated by the mode voltage generating circuit 500b is represented by Equation 1 below.

$$\text{Vmode\_500b} \text{=} \frac{R 2}{\left(r 1 \left‖R 1\right)\right) + R 2} ⋅ V D D \qquad \text{Equation 1:}$$

FIG. 5C illustrates an example mode voltage generating circuit 500c, in accordance with one or more embodiments.

Referring to FIG. 5C, an additional circuit configuration may not be connected to the contact point N1. That is, the contact point N1 may be floating. Accordingly, a voltage of the contact point N1 may be represented by Equation 2 below. That is, a mode voltage (Vmode_500c) generated by the mode voltage generating circuit 500c is represented by Equation 2 below.

$$\text{Vmode\_500c} \text{=} \frac{R 2}{R 1 + R 2} ⋅ V D D \qquad \text{Equation 2:}$$

FIG. 5D illustrates an example mode voltage generating circuit 500d, in accordance with one or more embodiments.

Referring to FIG. 5D, a resistor r2 may be connected between the contact point N1 and the ground. Accordingly, a voltage of the contact point N1 may be represented by Equation 3 below. That is, a mode voltage (Vmode_500d) generated by the mode voltage generating circuit 500d is represented by Equation 3 below.

$$\text{Vmode\_500d} \text{=} \frac{\left(r 2 \left‖R 2\right)\right)}{\left(r 2 \left‖R 2\right)\right) + R 1} ⋅ V D D \qquad \text{Equation 3:}$$

FIG. 5E illustrates an example mode voltage generating circuit 500e, in accordance with one or more embodiments.

Referring to FIG. 5E, the ground may be connected to the contact point N1. Accordingly, since a voltage of the contact point N1 becomes 0V (the ground), a mode voltage (Vmode_500e) generated by the mode voltage generating circuit 500e becomes the ground (0 V).

In an example, in FIG. 5B and FIG. 5D, by setting the values of the resistors r1 and r2 to various values, the mode voltage (Vmode) may be set to various levels.

Table 1 below shows an example of the output bit of the ADC 430 according to the mode voltage.

TABLE 1

| Mode voltage (Vmode) | ADC 430 output bit |
|---|---|
| VDD | 000 |
| $\frac{R 2}{\left(r 1 \left‖R 1\right)\right) + R 2} ⋅ V D D$ | 001 |
| $\frac{R 2}{R 1 + R 2} ⋅ V D D$ | 010 |
| $\frac{\left(r 2 \left‖R 2\right)\right)}{\left(r 2 \left‖R 2\right)\right) + R 1} ⋅ V D D$ | 011 |
| 0V (ground) | 100 |

As shown in Table 1, the ADC 430 may generate output bits of different values according to various mode voltages (Vmode).

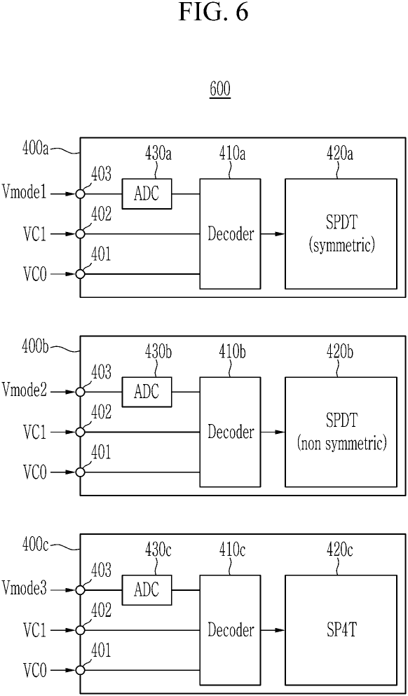

FIG. 6 illustrates an example RF switch circuit 600, in accordance with one or more embodiments.

As illustrated in FIG. 6, the example RF switch circuit 600 may include a first switch IC 400a, a second switch IC 400b, and a third switch IC 400c. The RF switch circuit 600 may be included in one front end module or device.

The first switch IC 400a may include a decoder 410a, a switch core 420a, and an ADC 430a. The switch core 420a may have a symmetric SPDT structure as illustrated in FIG. 2A. Additionally, in the first switch IC 400a, the switching control signals VC0 and VC1 may be respectively applied to the input pins 401 and 402, and the first mode voltage (Vmode1) may be applied to the input pin 403. The first mode voltage (Vmode1) may be one of the mode voltages of Table 1, and may correspond to the switch structure of the switch core 420a.

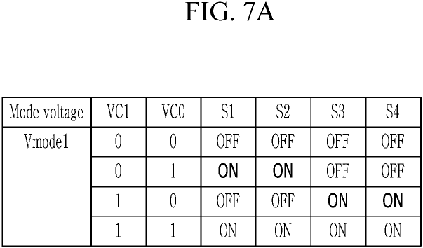

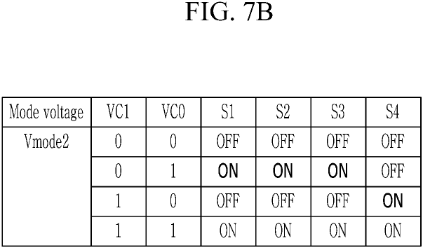

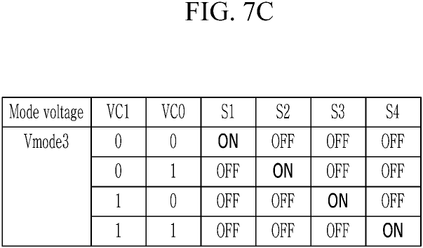

The ADC 430a may convert the first mode voltage (Vmode1) into a digital signal. That is, the ADC 430a may generate one of the output bits shown in Table 1. The decoder 410a may perform decoding by using the digital signal of the first mode voltage (Vmode1) and the switching control signals VC0 and VC1, and may generate a switching driving signal as illustrated in FIG. 7A.

FIG. 7A illustrates a switching driving signal according to the first mode voltage (Vmode1) and the switching control signals VC0 and VC1. Referring to FIG. 7A, in a switching control signal 01, a switch S1 and a switch S2 are turned on, and in a switching control signal 10, a switch S3 and a switch S4 are turned on. Accordingly, the switch core 420a may perform a symmetric SPDT operation.

The second switch IC 400b may include a decoder 410b, a switch core 420b, and an ADC 430b. The switch core 420b may have a non-symmetric SPDT structure as shown in FIG. 2B. Additionally, in the second switch IC 400b, the switching control signals VC0 and VC1 may be applied to the input pins 401 and 402, and the second mode voltage (Vmode2) may be applied to the input pin 403. The second mode voltage (Vmode2) may be one of the mode voltages of Table 1, and may correspond to the switch structure of the switch core 420b.

The ADC 430b may convert the second mode voltage (Vmode2) into a digital signal. That is, the ADC 430b may generate one of the output bits shown in Table 1. The decoder 410b may perform decoding by using the digital signal of the second mode voltage (Vmode2) and the switching control signals VC0 and VC1, and may generate a switching driving signal as shown in FIG. 7B.

FIG. 7B illustrates a switching driving signal according to the second mode voltage (Vmode2) and the switching control signals VC0 and VC1. Referring to FIG. 7B, in the switching control signal 01, the switch S1, the switch S2, and switch S3 are turned on, and in the switching control signal 10, the switch S4 is turned on. Accordingly, the switch core 420b may perform a non-symmetric SPDT operation.

Referring again to FIG. 6, the third switch IC 400c may include a decoder 410c, a switch core 420c, and an ADC 430c. The switch core 420c may have an SP4T structure as shown in FIG. 2C. Additionally, in the third switch IC 400c, the switching control signals VC0 and VC1 may be applied to the input pins 401 and 402, and the third mode voltage (Vmode3) may be applied to the input pin 403. The third mode voltage (Vmode3) may be one of the mode voltages of Table 1, and may correspond to the switch structure of the switch core 420c.

The ADC 430c may convert the third mode voltage (Vmode3) into a digital signal. That is, the ADC 430c may generate one of the output bits shown in Table 1. The decoder 410c may perform decoding by using the digital signal of the third mode voltage (Vmode3) and the switching control signals VC0 and VC1, and may generate a switching driving signal as shown in FIG. 7C. FIG. 7C illustrates a switching driving signal according to the third mode voltage (Vmode3) and the switching control signals VC0 and VC1. Referring to FIG. 7C, the switch S1 is turned on in a switching control signal 00, the switch S2 is turned on in the switching control signal 01, the switch S3 is turned on in the switching control signal 10, and the switch S4 is turned on in a switching control signal 11. Accordingly, the switch core 420c may perform a non-symmetric SP4T operation.

Referring to FIG. 7A to FIG. 7C, the RF switch circuit 600, in accordance with one or more embodiments, may generate different switching driving signals according to the mode voltage (Vmode) set in the switch IC even though the switching control signals VC0 and VC1 inputted from the outside are the same. A total sum of the number of the switches in the switch core 420a, the number of the switches in the switch core 420b, and the number of the switches in the switch core 420c is 12. Generally, a switching control signal of at least 4 bits is required to control 12 switches, and accordingly, 4 input pins are required for one switch IC. In contrast, since the RF switch circuit 600 according to the embodiment requires three input pins 401, 402, and 403 in one switch IC, the number of the pins may be reduced. That is, the RF switch circuit 600 according to the embodiment may reduce the number of the input pins by setting the mode voltage to different voltages according to the switch structure of the switch core.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A radio frequency (RF) switch circuit, comprising:
a first switch integrated circuit (IC) comprising a first switch core which has a first switch structure, a first input pin to which a first switching control signal is inputted, and a second input pin to which a first mode voltage corresponding to the first switch structure is inputted; and
a second switch IC comprising a second switch core which has a second switch structure, a third input pin to which a second switching control signal is inputted, and a fourth input pin to which a second mode voltage corresponding to the second switch structure is inputted.

2. The RF switch circuit of claim 1, wherein:
the second switch structure is different from the first switch structure, and the second mode voltage has a different voltage level from a voltage level of the first mode voltage.

3. The RF switch circuit of claim 2, wherein:
the first switch core comprises a plurality of first switches,
the second switch core comprises a plurality of second switches, and
a connecting structure between terminals in the plurality of first switches is different from a connecting structure between terminals in the plurality of second switches.

4. The RF switch circuit of claim 3, wherein:
each of the plurality of first switches is configured to have a single pole single throw (SPST) structure, and
each of the plurality of second switches is configured to have an SPST structure.

5. The RF switch circuit of claim 2, wherein:
a structure with respect to a pole and a throw with which the first switch structure is formed is different from a structure with respect to a pole and a throw with which the second switch structure is formed.

6. The RF switch circuit of claim 1, wherein:
the first switch IC further comprises a first decoder configured to perform a decoding operation by implementing the first switching control signal and the first mode voltage, and generate a switching driving signal, and
the second switch IC further comprises a second decoder configured to perform a decoding operation by implementing the second switching control signal and the second mode voltage, and generate a switching driving signal.

7. The RF switch circuit of claim 6, wherein:
the first switch IC further comprises a first analog-digital converter configured to convert the first mode voltage to a digital signal, and output the converted first mode voltage to the first decoder, and
the second switch IC further comprises a second analog-digital converter configured to convert the second mode voltage into a digital signal and output the converted second mode voltage to the second decoder.

8. The RF switch circuit of claim 2, wherein:
the first switching control signal and the second switching control signal are configured to have a same number of bits.

9. The RF switch circuit of claim 8, wherein:
the first switching control signal and the second switching control signal are each a general-purpose input output (GPIO).

10. The RF switch circuit of claim 3, wherein:
each of the plurality of first switches comprises a plurality of transistors configured to form one of a T structure and a pi ( π ) structure, and
each of the plurality of second switches comprises a plurality of transistors configured to form one of a T structure and a pi ( π ) structure.

11. The RF switch circuit of claim 1, wherein:
each of the first input pin and the third input pin comprises a plurality of input pins, and
a number of the first input pins is equal to a number of the third input pins.

12. A switch integrated circuit (IC), comprising:
a switch core comprising a plurality of switches, and in which a pole and a throw are formed by a connecting structure between terminals in the plurality of switches;
a first input pin to which a switching control signal that controls the plurality of switches is inputted; and
a second input pin to which a mode voltage corresponding to the connecting structure is inputted.

13. The switch IC of claim 12, wherein:
each of the plurality of switches is configured to have a single pole single throw (SPST) structure.

14. The switch IC of claim 12, further comprising:
a decoder configured to perform a decoding operation based on the switching control signal and the mode voltage.

15. The switch IC of claim 14, further comprising:
an analog-digital converter configured to convert the mode voltage into a digital signal to output the converted mode voltage to the decoder.

16. The switch IC of claim 12, wherein:
the switching control signal is a general-purpose input output (GPIO).

17. The switch IC of claim 12, wherein:
each of the plurality of switches comprises a plurality of transistors configured to form one of a T structure and a pi ( π ) structure.
